(19) United States
(12) Patent Application Publication
(10) Pub. No.: US 2019/0181882 A1
(43) Pub. Date: Jun. 13, 2019

(54) DETERMINING ELEMENTS OF BASE MATRICES FOR QUASI-CYCLIC LDPC CODES HAVING VARIABLE CODE LENGTHS

(71) Applicant: TELEFONAKTIEBOLAGET LM ERICSSON (PUBL), Stockholm (SE)

(72) Inventors: Yufei BLANKENSHIP, KILDEER, IL (US); Mattias ANDERSSON, SUNDBYBERG (SE)

(21) Appl. No.: 16/324,995

(22) PCT Filed: Aug. 9, 2017
(86) PCT No.: PCT/IB2017/054868

§ 371 Date: Feb. 12, 2019

Related U.S. Application Data
(60) Provisional application No. 62/374,478, filed on Aug. 12, 2016.

(51) Int. Cl. H03M 13/11; H03M 13/00

(52) U.S. Cl. CPC H03M 13/116; H03M 13/616

(57) ABSTRACT

Encoding/decoding method comprising the derivation of the elements of base matrices for Quasi-Cyclic LDPC, codes using different lifting sizes to obtain variable code lengths. The cyclic shift values of smaller lifting sizes Z are derived from stored elements a base matrix corresponding to a maximal lifting sizes Zmax by applying right shifting (ceil(log 2Z/Zmax) times) to a binary vector representation of all non-negative stored elements of the base matrix corresponding to Zmax. The right shifting operation may be applied only when the stored cyclic shift value corresponding to Zmax is larger than the smaller lifting size Z. Application to an encoder/decoder within a wireless communications network, a magnetic storage system or a solid-state drive system.

### CROSS REFERENCE TO RELATED APPLICATIONS

This application claims the benefit of priority to previously filed U.S. Provisional Patent Application No. 62/374,478 entitled “SHIFT SIZES OF PARITY CHECK MATRICES” filed on Aug. 12, 2016, the contents of which are incorporated herein by reference.

### TECHNICAL FIELD

This disclosure pertains generally to coding using low density parity check (LDPC) codes, and more particularly to shift-sizes of quasi cyclic parity check matrices associated with LDPC codes.

### BACKGROUND

Low-Density Parity-Check (LDPC) codes comprise linear block codes defined by a very sparse parity-check matrix H, and are often proposed as the channel coding solutions for modern wireless communication systems, magnetic storage systems and solid-state drive systems. Medium-rate LDPC codes are used in standards, such as DVB-S2, WiMax (IEEE 802.16e), and wireless LAN (IEEE 802.11n). Furthermore, high-rate LDPC codes have been selected as the channel coding scheme for mmWave WPAN (IEEE 802.15.3c). These recent successes of LDPC codes appear in part in response to their structures, for example as these structures are readily implemented in partially-parallel decoders. An important class of LDPC codes, called quasi-cyclic LDPC (QC-LDPC), have been adopted in all the standards mentioned above.

QC-LDPC decoders are known to have a significantly higher throughput than the decoders of random sparse matrices. IEEE Std 802.11™-2012 “Part 11: Wireless LAN Medium Access Control (MAC) and Physical Layer (PHY) Specifications” providing additional background information on LDPC encoding.

5G wireless networks, such as 3GPP (Third Generation Partnership) New Radio (NR) developed to support requirements such as enhanced mobile broadband (eMBB), may also use channel coding schemes such as low-density parity check (LDPC).

Low-density parity-check (LDPC) codes are defined through a sparse parity-check matrix (PCM). As illustrated in FIG. 1, the parity check matrix, also denoted herein as H, can be mapped to a bipartite graph composed of check nodes and variable nodes, where the rows and columns of the PCM correspond to check nodes and variable nodes, respectively. Each entry h(i,j)=1 in the PCM corresponds to an edge between a check node and a variable node in the graph.

The code rate of the LDPC code is defined as the number of information bits k divided by the number of coded bits n, R=k/n, where n is the number of columns in the PCM and k equals the number of columns minus the number of rows of the PCM, m. In other words, the PCM or H matrix is of dimension (m rows)-by-(n columns), where m=(n-k). If all coded bits are not transmitted, the code rate is calculated based on the number of transmitted coded bits instead, that is, R=k/n_transmitted.

As already noted, an important class of LDPC codes are quasi-cyclic LDPC (QC-LDPC) codes. The PCM or H matrix of a QC-LDPC code of size m×n can be represented by a base matrix H_base of size m/Z and n/Z, and a lifting factor (or lift size) Z. Each entry of H_base contains either the number −1 or one or more numbers between 0 and Z−1. A ‘shift size’ is an entry in the base matrix H_base that is not equal to −1. If an entry in the base matrix H_base that is not equal to −1 has more than one integer, it represents as many ‘shift sizes’ as integers are in the entry.

Let i and j be integers between 0 and (m/Z−1), and 0 and (n/Z−1) respectively. Then the submatrix formed from the entries in rows Z*i to Z*(i+1)−1 and columns Z*j to Z*(j+1)−1, are determined by the entry in row i and column j of H_base in the following way:

If H_base(i,j)=−1, then the submatrix in the expanded binary matrix H is equal to the Z by Z zero matrix.

If H_base(i,j) contains one or more integers k₁, k₂, . . . k_{d} between 0 and Z−1, the submatrix in the expanded binary matrix H is equal to the sum of the shifted identity matrices P_k₁+P_k₂+ . . . +P_k_{d}, where each Z×Z submatrix P_k is obtained from the Z by Z identity matrix by cyclically shifting the columns to the right k times.

A compact way of defining a family of LDPC codes with the same rate but different number of code bits is sometimes possible. For example, in the IEEE 802.16e standard, the set of lift sizes is Z={24, 28, 32, . . . , 92, 96}. The base matrix for a given code rate is provided for Zmax=96 and is denoted herein as H_base_Zmax. Then the base matrices H_base_Z for each of the smaller Z, Z={24, 28, 32, . . . , 92} can be obtained from the base matrix H_base_Zmax by implementing one of the following ways:

Alternative 1:

If H_base_Zmax(i,j)=−1, H_base_Z(i,j)=−1

Otherwise the elements of H_base_Z(i,j) are derived from the elements of H_base_Zmax(i,j) by: H_base_Z(i,j)=modulo(H_base_Zmax(i,j), Z).

Alternative 2:

If H_base_Zmax(i,j)=−1, H_base_Z(i,j)=−1

Otherwise the elements of H_base_Z(i,j) are derived from the elements of H_base_Zmax(i,j) by: H_base_Z(i,j)=floor(H_base_Zmax(i,j)x Z/Zmax).

The above noted ways of deriving shift sizes are complex and/or inefficient. There is a need for improved methods of deriving shift sizes of quasi-cyclic parity check matrix of smaller Z from a parity check matrix of larger Z, as well as a need for associated systems, nodes, devices operable to implement such methods.

### SUMMARY

Particular aspects and/or exemplary embodiments disclosed herein may alleviate some of the needs described above, in part or entirely. Particular aspects and/or exemplary embodiments disclosed herein provide methods, communication nodes and devices and systems for deriving shift sizes of quasi-cyclic parity check matrix of smaller Z from a parity check matrix of larger Z. According to some aspects, disclosed methods comprise shifting of binary representation of integer to generate shift sizes in parity check matrices of smaller Z. Furthermore, communication nodes, devices and systems according to disclosed embodiments are configured to shift binary representation of integer to generate shift sizes in parity check matrices of smaller Z.

According to one aspect, a method comprises deriving the elements of a base matrix H_base_Z with lower Z from a base matrix with a maximum Z (Zₘₐₓ), H_base_Zmax. The deriving comprises right shifting a binary vector representation of all non-negative elements of the base matrix. The right shifting may occur one or more times. In some embodiments, the right shifting may occur t times, where t=ceil(log 2(Zmax/Z). The derived elements of a base matrix H_base_Z may be used to generate a parity code matrix H for an LDPC code. According to one embodiment, the right shifting is applied only when H_base_Zmax(i,j)>=Z.

According to an embodiment, the method further comprises doing the following assignment operation: H_base_Z(i,j)=H_base_Zmax(i,j), when H_base_Zmax(i,j)<Z.

According to an embodiment, the method further comprises encoding a transport block using the LDPC code and transmitting the transport block.

According to an alternate embodiment, the method further comprises receiving a transport block and decoding the transport block using the LDPC code.

According to another aspect, a communication node comprising a processor and a memory is provided. The processor is operable to perform steps according to embodiments of methods disclosed herein.

According to some aspects, methods comprising deriving shift sizes of the H matrix using binary-vector operation is provided. Such methods may be used for LDPC coding. Devices, computer programs and computer readable media configured to process and/or store instructions for such methods are also provided.

Advantages according to some embodiments include simpler hardware implementation. In particular, some of the embodiments allow shifting of a binary vector, which does not involve operations like multiplication/addition/division/subtraction.

Hence it is very easy to implement in hardware. Alternatively or additionally, some embodiments, avoid saving the numerous parity-check matrices in memory. For some embodiments a large proportion of the PCM entries may stay the same while deriving a H matrix of lifting factor Z from that of lifting factor Z. This can be leveraged by hardware implementation. In some embodiments, the exact proportion of unchanged PCM entries depends on the lifting factor Z, Zmax, and the entries in PCM of Zmax of some embodiments is that shift sizes of quasi-cyclic parity check matrix of smaller Z from parity check matrix of larger Z.

### BRIEF DESCRIPTION OF THE DRAWINGS

For a more complete understanding of the embodiments and their features and advantages, reference is now made to the following description, taken in conjunction with the accompanying drawings, in which:

FIG. 1 illustrates an example of FIG. 1 a parity-check matrix and its corresponding bipartite graph;

FIG. 2 is a block diagram illustrating a communication system;

FIG. 3 is a flow diagram of an example method, according to some aspects of the present disclosure;

FIG. 4 is a flow diagram of an example method, according to some aspects of the present disclosure;

FIG. 5A is a block diagram illustrating an example embodiment of communication node, according to some aspects of the present disclosure;

FIG. 5B is a block diagram illustrating example components of a communication node according to some aspects of the present disclosure;

### DETAILED DESCRIPTION

The description herein sets forth numerous specific details. It is understood, however, that embodiments may be practiced without these specific details. In other instances, well-known circuits, structures and techniques have not been shown in detail in order not to obscure the understanding of this description. Those of ordinary skill in the art, with the included descriptions, will be able to implement appropriate functionality without undue experimentation.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that one skilled in the art may recognize the feasibility of implementing such feature, structure, or characteristic in connection with other embodiments, whether or not explicitly described.

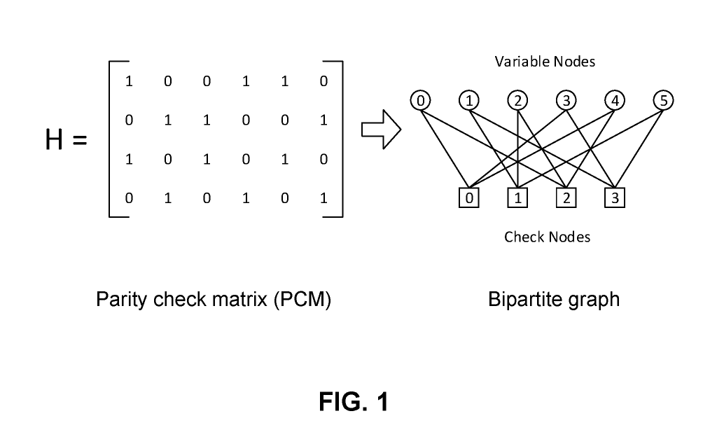

In some embodiments, LDPC codes with PCM matrices derived as described herein may be used to encode/decode signals, such as wireless signals in a wireless communications network, or for magnetic storage systems and solid-state drive systems. Particular embodiments are described with reference to FIGS. 1-5B of the drawings, like numerals being used for like and corresponding parts of the various drawings. A communication system is used throughout this disclosure as an example system using LDPC coding, but a person skilled in the art will recognize the principles presented herein may apply to other systems and technologies as well.

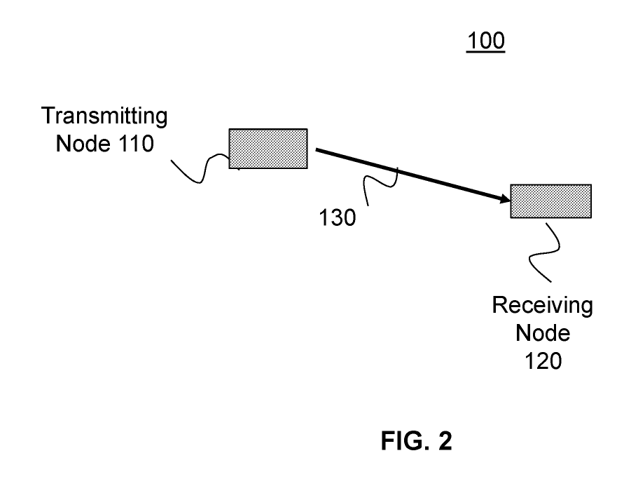

FIG. 2 is a block diagram illustrating an example communication system 100, according to an embodiment of the disclosure. Communication system 100 includes one or more communication nodes, such as receiving nodes 120 (only one shown) and transmitting nodes 110 (only one shown). The communication nodes 110, 120 can be any device capable of data communication, where the communication can be wired, wireless, etc. Examples of communication nodes are wireless or wired devices, mobile phones, smart phones, laptop computers, tablet computers, MTC devices, or any other devices that can provide data communication, base stations, user equipment (UE), eNodeBs, satellites, sensors, radio communication device, target device, device to device (D2D) UE, machine type UE or UE capable of machine to machine communication (M2M), a sensor equipped with UE, iPAD, Tablet, mobile terminals, smart phone, laptop embedded equipped (LEE), laptop mounted equipment (LME), USB dongles, Customer Premises Equipment (CPE), base station, radio base station, base transceiver station, base station controller, network controller, evolved Node B (eNB), Node B, multi-RAT base station, Multi-cell/multicast Coordination Entity (MCE), relay node, access point, radio access point, Remote Radio Unit (RRU) Remote Radio Head (RRH), a core network node (e.g., MME, SON node, a coordinating node, etc.), or even an external node (e.g., 3rd party node, a node external to the current communication system 100), etc.

In general, receiving node 120 receives signals 130 from transmitting node 110. For example, receiving node 120 and transmitting node 110 may communicate wired or wireless signals 130 containing voice traffic, data traffic, and/or control signals.

Signals 130 may comprise transport blocks. The signals may be encoded/decoded according to any of the LDPC codes or coding methods derived as described herein. Transmitting node 110 and receiving node 120 may include transmitters and receivers, respectively, and encoders and decoders, respectively, for encoding and decoding signals according to any of the LDPC codes or coding methods and principles of embodiments described herein.

Each transmitting node 110 may have a single transmitter or multiple transmitters for transmitting signals 130 to receiving node 120. In some embodiments, transmitter and receiver nodes 110, 120 may comprise a multi-input multi-output (MIMO) system. Similarly, each receiver node 120 may have a single receiver or multiple receivers for receiving signals 130 from transmitter node 110. In addition, in some embodiments, a communication node 110, 120 may include transmitter and receivers, and encoders and decoders.

The communications system 100 may be part of a wireless network, using any suitable radio access technology, such as long term evolution (LTE), LTE-Advanced, NR, UMTS, HSPA, GSM, cdma2000, WiMax, WiFi, and/or other suitable radio access technology, or part of any other network, not necessarily wireless. Communication system 100 may include any suitable combination of one or more communication technologies. For purposes of example, various embodiments may be described within the context of certain radio access technologies. However, the scope of the disclosure is not limited to the examples and other embodiments could use different radio access technologies.

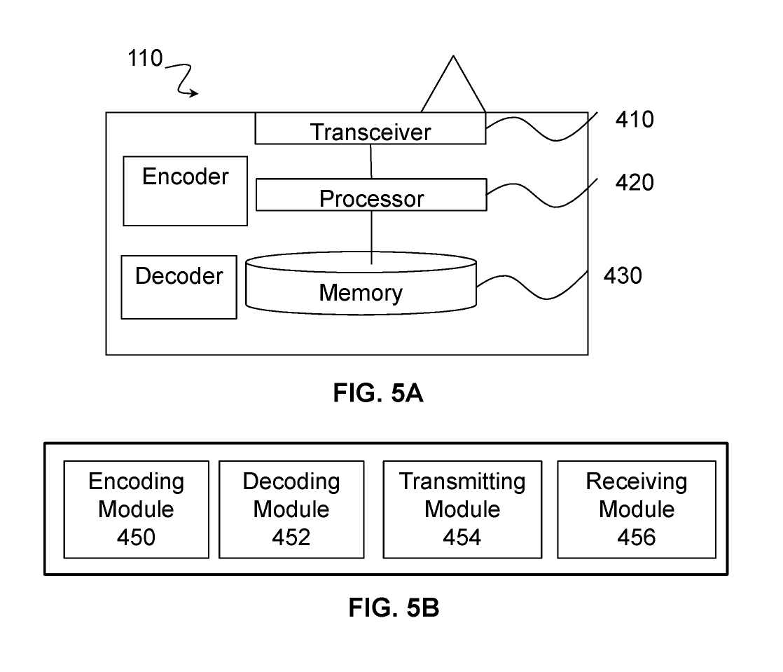

A communication node (110,120) may include any suitable combination of hardware and/or software. For example, in particular embodiments, communication node 110, 120, may include the components described below with respect to FIG. 5A.

Furthermore, functions described herein as being performed by communication node 110, 120 may be distributed over a plurality of transmitting/receiving nodes such as wireless devices and/or network nodes.

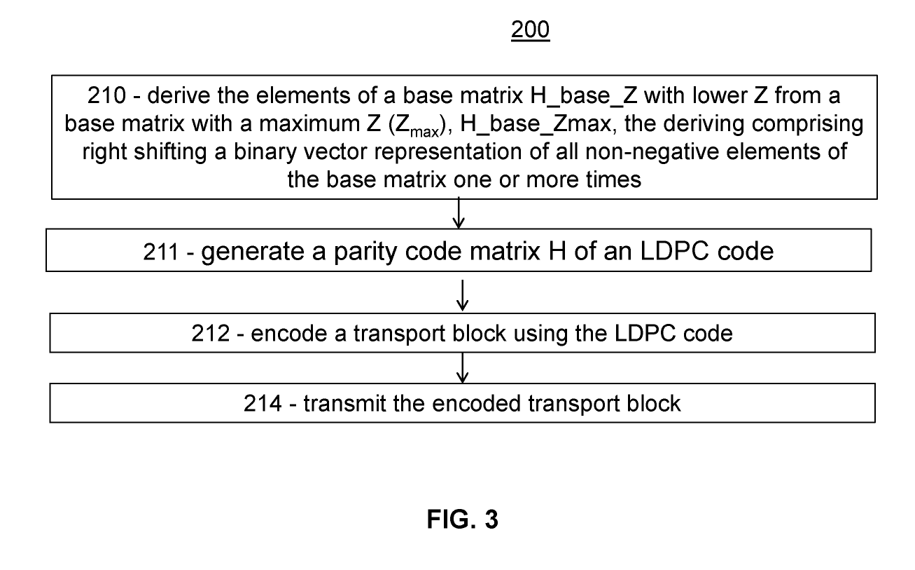

FIG. 3 is a flow diagram of an example method 200 in a communication node 110 encoding a transport block, according to some embodiments. In particular embodiments, one or more steps of method 200 may be performed by components of communication system 100 described with reference to FIGS. 2-5B.

Method 200 begins at step 210, where a communication node derives the elements of a base matrix H_base_Z with lower Z from a base matrix with a maximum Z (Zmax), H_base_Zmax, the deriving comprising right shifting a binary vector representation of all non-negative elements of the base matrix.

At step 211, the communication node generates the parity code matrix H of an LDPC code, based on element of H_Base_Z derive in step 210.

At step 212, the communication node 110 encodes a transport block using the LDPC code. A transport block is used in this embodiments as an example, but the signal may be represented differently. As another example, in particular embodiments, a wireless device may encode a transport block using a LDPC code derived and implemented according to principles described herein.

At step 214, the communication node 110 transmits the encoded transport block. For example, a wireless device, such as UE, may transmit the encoded transport block to a network node, such as an eNB or a network node may transmit the encoded transport block to a wireless device.

Modifications, additions, or omissions may be made to method 200 illustrated in FIG. 3. Additionally, one or more steps in method 200 may be performed in parallel or in any suitable order.

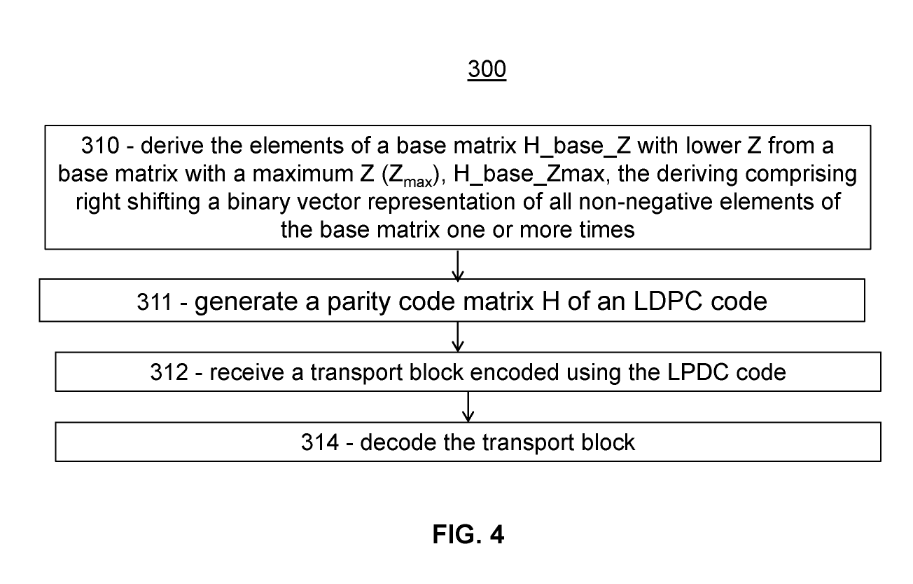

FIG. 4 is a flow diagram of an example method in a communication node 120 of decoding a transport block, according to some embodiments. In particular embodiments, one or more steps of method 300 may be performed by components of, communication system. 100

Method 300 begins at step 310, where a communication node derives the elements of a base matrix H_base_Z with lower Z from a base matrix with a maximum Z (Zmax), H_base_Zmax, the deriving comprising right shifting a binary vector representation of all non-negative elements of the base matrix, one or more times.

At step 311, the communication node generates the parity code matrix H of an LDPC code, based on element of H_Base_Z derived in step 310. At step 312, where the communication node 120 receives a transport block encoded using the LPDC code. A transport block is used in this embodiments as an example, but the signal may be represented differently. For example, in particular embodiments a wireless device, such as a UE, may receive an encoded transport block from a network node, such as a eNB. As another example, in particular embodiments a wireless device may receive an encoded transport block from another wireless device.

At step 314, the communication node decodes the transport block. For example, in particular embodiments communication node may decode the transport block using an LDPC codes derived and implemented according to any of the principles described herein.

Modifications, additions, or omissions may be made to method 300 illustrated in FIG. 4. Additionally, one or more steps in method 200 may be performed in parallel or in any suitable order.

FIG. 5A is a block diagram illustrating an example embodiment of a communication node, 110, 120. Particular examples include a mobile phone, a smart phone, a PDA (Personal Digital Assistant), a portable computer (e.g., laptop, tablet), a sensor, a modem, a machine type (MTC) device/machine to machine (M2M) device, laptop embedded equipment (LEE), laptop mounted equipment (LME), USB dongles, a device-to-device capable device, a NB-IoT device, an eNodeB, a nodeB, a base station, a wireless access point (e.g., a Wi-Fi access point), a low power node, a base transceiver station (BTS), a transmission point or node, a remote RF unit (RRU), a remote radio head (RRH), or other radio access node or any other device that can provide wireless communication. The communication node includes transceiver 410, processor 420, and memory 430. The communication node may further include and encoder and/or a decoder. In some embodiments, transceiver 410 facilitates transmitting signals to and receiving signals from transmitting node 110 (e.g., via an antenna), processor 420 executes instructions to provide some or all of the functionality described herein as provided by the communication node, and memory 430 stores the instructions executed by processor 420.

Processor 420 includes any suitable combination of hardware and software implemented in one or more integrated circuits or modules to execute instructions and manipulate data to perform some or all of the described functions of the communication node. In some embodiments, processor 420 may include, for example, one or more computers, one more programmable logic devices, one or more central processing units (CPUs), one or more microprocessors, one or more applications, and/or other logic, and/or any suitable combination of the preceding. Processor 420 may include analog and/or digital circuitry configured to perform some or all of the described functions of communication node 110, 120. For example, processor 420 may include resistors, capacitors, inductors, transistors, diodes, and/or any other suitable circuit components.

Memory 430 is generally operable to store computer executable code and data. Examples of memory 430 include computer memory (e.g., Random Access Memory (RAM) or Read Only Memory (ROM)), mass storage media (e.g., a hard disk), removable storage media (e.g., a Compact Disk (CD) or a Digital Video Disk (DVD)), and/or or any other volatile or non-volatile, non-transitory computer-readable and/or computer-executable memory devices that store information.

In particular embodiments, processor 420 in communication with transceiver 410 communicates signals with receiving node 120 or other transmitting node 110. In particular embodiments, the signals may be encoded and/or decoded using any of the LDPC coding principles described herein. Other embodiments of the communication node may include additional components (beyond those shown in FIG. 5A) responsible for providing certain aspects of the communication node's functionality, including any of the functionality described above and/or any additional functionality (including any functionality necessary to support the solution described above).

FIG. 5B is a block diagram illustrating example components of a communication node 110, 120. The components may include encoding module 450 and/or decoding module 452, transmitting module 454, and/or receiving module 456.

Encoding module 450 may perform the encoding functions of communication node 110. 120. For example, encoding module 450 may encode transport blocks using a LDPC code derived according to principles described herein. In certain embodiments, encoding module 450 may include or be included in processor 420. In particular embodiments, encoding module 450 may communicate with transmitting module 454.

Decoding module 452 may perform the decoding functions of rec communication node 110, 120. For example, decoding module 452 may decode transport blocks using an LDPC code derived according to principles described herein. In certain embodiments, decoding module 452 may include or be included in processor 420. In particular embodiments, decoding module 452 may communicate with receiving module 456.

Transmitting module 454 may perform the transmitting functions of communication node 110. For example, transmitting module 454 may transmit encoded transport blocks to network node 120. In certain embodiments, transmitting module 454 may include or be included in processor 420. Transmitting module 454 may include circuitry configured to transmit radio signals. In particular embodiments, transmitting module 454 may communicate with encoding module 450.

Receiving module 456 may perform the receiving functions of receiving node 120. For example, receiving module 456 may receive encoded transport blocks from network node 120. In certain embodiments, receiving module 456 may include or be included in processor 420. Receiving module 456 may include circuitry configured to receive radio signals. In particular embodiments, receiving module 456 may communicate with decoding module 452.

According to one aspect, a method to derive H_base_Z of lift size Z, Z≠Zmax, from H_base_Zmax of max Z is disclosed. The method comprises deriving H_base_Z(i,j) from the binary representation of H_base_Zmax(i,j).

### Embodiment 1

In one embodiment, a method of deriving shift sizes for parity check matrices comprises deriving the elements of a base matrix H_base_Z with lower Z from a base matrix with the largest Z (or maximum Z, i.e., Zmax), H_base_Zmax. The derivation may comprise right shifting the binary vector representation of the non-negative elements of the base matrix. To ensure that the non-negative elements of the new base matrix fall in the range 0 to Z−1, a parameter, such as t, is set as t=ceil(log 2(Zmax/Z)) and the binary representations of the non-negative elements of H_base_Zmax are right shifted t times. Therefore, the elements of H_base_Z are given by:
a) If H_base_Zmax(i,j)=−1, H_base_Z(i,j)=−1
b1) Otherwise, the elements of H_base_Z(i,j) are derived by taking the binary representations of the elements of H_base_Zmax(i,j) and right shifting them t times.
   It is noted that for the entries H_base_Zmax(i,j)=0, H_base_Z (i,j)=H_base_Zmax(i,j)=0. Hence these entries can also be set aside like those in Step a), where H_base_Z (i,j)=H_base_Zmax(i,j)=−1.

The right shift operation is hardware efficient. An alternative description of applying the right shift operation of the binary representation t times is that the non-negative elements of H_base_Z(i,j) are given by dividing the non-negative elements of H_base_Zmax(i,j) with 2^{t} followed by rounding down. That is, step b1) above can be replaced by:
b2) Otherwise, derive the elements of H_base_Z(i,j) from the elements of H_base_Zmax(i,j) by: H_base_Z(i,j)=floor(H_base_Zmax(i,j)/2^{t}).

Embodiment 1 may be particularly effective when applied to a family of PCM of the same code rate, where the lifting factors (i.e., the different Z values) for the family are related by: Z_p=Zmin*2^{p}. The maximum lifting factor is Zmax=Zmin*2^{pmax}. In this case, step b1), and alternate step b2), become:
b3) Otherwise. derive the elements of H_base_Z(i,j) from the elements of H_base_Zmax(i,j) by: right shifting the binary representations of the non-negative elements of H_base_Zmax t times, where t=pmax−p. or, equivalently: H_base_Z(i,j)=floor(H_base_Zmax(i,j)/2^{t}).

Example of derivation using Embodiment 1:

The H_base matrix for 802.11n rate 5/6 matrix for n=1944, with Zmax=81 is,
H_base_Z81_R5_6=[13 48 80 66 4 74 7 30 76 52 37 60−1 49 73 31 74 73 23 −1 1 0 −1 −1 69 63 74 56 64 77 57 65 6 16 51 −1 64 −1 68 9 48 62 54 27 −1 0 0 −1 51 15 0 80 24 25 42 54 44 71 71 9 67 35 −1 58 −1 29 −1 53 0 −1 0 0 16 29 36 41 44 56 59 37 50 24 −1 65 46 55 2 −1 4 −1 73 52 1 −1 −1 0];
The derived rate 5/6 H_base matrix for n=648, with Z=27, is:
H_base_Z27_R5_6=[3 12 20 16 1 18 1 7 19 13 9 15 −1 12 18 7 18 18 5 −1 0 0 −1 −1 17 15 18 14 16 19 14 16 1 4 12 −1 16 −1 17 2 12 15 13 6 −1 0 0 −1 12 3 0 20 6 6 10 13 11 17 17 2 16 8 −1 14 −1 7 −1 13 0 −1 0 0 4 7 9 10 11 14 14 9 12 6 −1 16 1 16 13 −1 −1 18 13 0 −1 −1 0];

In the above derivation, Step b1), or equivalently b2), is applied. Here t=ceil(log 2(81/27))=2. Since the code sizes of n=1944 and n=648 are not related by a factor of power-of-2, Step b3) in Embodiment 1 does not apply. Either step b1) or b2) of Embodiment 1 can be used to arrive at above H_base matrix for n=648.

### Embodiment 2

Embodiment 2 is a modification of Embodiment 1 in which the shifting operation is applied only if the shift size is greater than or equal to the lower Z.
a) If H_base_Zmax(i,j)<Z, H_base_Z(i,j)=H_base_Zmax(i,j);
The above condition means that Step a) in Embodiment 1 is included as a special case: If H_base_Zmax(i,j)=−1, H_base_Z(i,j)=−1
b) Otherwise, derive the elements of H_base_Z(i,j) by one of Step b1), or b2) or b3) in Embodiment 1

Example of derivation using Embodiment 2:

From the H_base matrix for 802.11n rate 5/6 matrix for n=1944, the derived H matrix for n=648, with Z=27, using Embodiment 2, is:
H_base_Z27_R5_6=[13 12 20 16 4 18 7 7 19 13 9 15 −1 12 18 7 18 18 23 −1 1 0 −1 −1 17 15 18 14 16 19 14 16 6 16 12 −1 16 −1 17 9 12 15 13 6 −1 0 0 −1 12 15 0 20 24 25 10 13 11 17 17 9 16 8 −1 14 −1 7 −1 13 0 −1 0 0 16 7 9 10 11 14 14 9 12 24 −1 16 4 16 13 −1 4 −1 18 13 1 −1 −1 0];

Since the code sizes of n=1944 and n=648 are not related by a factor of power-of-2, Step b3) in Embodiment 1 does not apply. Either step b1) or b2) of Embodiment 1 can be used to arrive at above H_base matrix for n=648.

An advantage of embodiments 1 and 2 is that shifting of a binary vector does not involve operations like multiplication/division/addition/subtraction. Hence it is much easier to implement in hardware than other known methods. Embodiments 1 and 2 also allow to avoid saving numerous parity-check matrices in memory. In addition, according to Embodiment 2, due to its clause a), a large proportion of the PCM entries may stay the same while deriving a H matrix of lifting factor Z from that of lifting factor Z. This aspect can be leveraged by hardware implementation. The exact proportion of unchanged PCM entries depends on the lifting factor Z, Zmax, and the entries in PCM of Zmax.

The disclosed methods can be generalized to base matrices where any entry H_base_Zmax(i,j) is composed of multiple integers H_base_Zmax(i,j)={h_{i,j,1}, h_{i,j,2}, . . . , h_{i,j,d}}. That is, the submatrix (i,j) in the expanded binary matrix H is equal to the sum of two or more shifted identity matrices P_k₁+P_k₂+ . . . +P_k_{d}, d>1. Here P_kᵢ is a Zmax-by-Zmax submatrix, obtained from the Zmax-by-Zmax identity matrix by cyclically shifting the columns to the right kᵢ times. In this case, a derivation method, such as in Embodiment 1 or Embodiment 2, is applied to each shift sizes {h_{i,j,1}, h_{i,j,2}, . . . , h_{i,j,d}} for H_base_Zmax(i,j). Using Step a) and Step b2) in Embodiment 1 to illustrate, the procedure is generalized to:
a) If H_base_Zmax(i,j)=−1, H_base_Z(i,j)=−1 b2) Otherwise, derive the elements of H_base_Z(i,j) from the elements of H_base_Zmax(i,j) by: H_base_Z(i,j)={floor(h_{i,j,1}/2^{t}), floor(h_{i,j,2}/2^{t}), . . . , floor(h_{i,j,d}/2^{t})}, d>=1. This generalized description includes d=1 as a special case.
   It may be the case that after applying the method according to Embodiment 1 or 2 to derive new shift sizes, there might be fewer unique derived shift sizes than before applying the method. Let f(h_{i,j,1}), f(h_{i,j,2}), . . . , f(h_{i,j,d}) denote the derived shift sizes after applying Embodiment 1 or Embodiment 2. In the case under discussion, f(h_{i,j,k})=f(h_{i,j,1}) for some k≠l.

Two embodiments for handling the duplication f(h_{i,j,k})=f(h_{i,j,1}) are disclosed:

### Embodiment 3

In Embodiments 1 and 2 or other embodiments (see note below), one may keep only the unique shift sizes after deriving new shift sizes.

### Embodiment 4

In Embodiments 1 and 2, or other embodiments (see note below), one may order the derived shift sizes from smallest to largest. Go through all the derived shift sizes. If a shift size is not in the output set, add it to the output set and continue with the next shift size. If a shift size is already in the output set, add 1 to it and apply the modulo Z operation. If the new number is not in the output set, add it to the output set and continue with the next shift size. The output set is an initially empty set of available shifts. It is denoted by S in the algorithm below. If at any time the output set contains all numbers {0, . . . , Z−1}, stop. The output set becomes the new set of derived shift sizes.

Input: a set of d integers {x₁, x₂, ..., x_{d}}, which are not necessarily unique,
and an integer Z.
Output: a new set S of integers containing only unique entries.

| | |
|---|---|
| Step 1: | Let S ← { }, and k ← 1. |
| Step 2: | While xₖ belongs to S |

Let xₖ ← mod(xₖ + 1, Z)

| | |
|---|---|
| | End While |
| Step 3: | If xₖ does not belong to S |

add xₖ to S
k ← k + 1.

| | |
|---|---|
| | End If |
| Step 4: | If k = d + 1 or if S = {0, ..., Z−1} |

Stop and return S

Else

Go to Step 2.

End If

In the above description, { } denotes the empty set, and mod(xₖ+1, Z) denotes the remainder of xₖ+1 after dividing by Z.

Note that Embodiments 3 and 4 can be applied to a set of non-unique shift sizes derived in other ways than Embodiments 1 and 2. For example Embodiment 3 and Embodiment 4 can be used with the set of derived shift sizes {f(h_{i,j,1}), f(h_{i,j,2}), . . . , f(h_{i,j,d})} obtained using the modulo- or scaling methods. The modulo- and scaling-methods used in 802.16e were mentioned in the introduction.

Example: Assume that Z=5, and the set of derived shift sizes {f(h_{i,j,1}), f(h_{i,j,2}), . . . , f(h_{i,j,d})} are {3,3,4}. After using Embodiment 3 the new set of shift sizes becomes {3,4}. After using Embodiment 4, the new set of shift sizes becomes {0, 3, 4}. The new set of shift sizes {3,4} or {0, 3, 4} is then used in expanding the base matrix into the binary parity check matrix H of cyclic shift size Z=5.

Other Comments

Note that while the embodiments described assume Z<Zmax in shift size derivation for defining new parity check matrices, the disclosed principles can be adapted to use for lifting factor Z>Zmax. In the later case, shift sizes may not be able to utilize the full granularity from H_base_Z(i,j)=0 to H_base_Z (i,j)=Z−1. Nevertheless, a quasi-cyclic parity check matrix can be constructed for Z>Zmax.

Some embodiments of the disclosure may provide one or more technical advantages. Some embodiments may benefit from some, none, or all of these advantages. Other technical advantages may be readily ascertained by one of ordinary skill in the art. A technical advantage of some embodiments is that the LDPC coding according to principles described herein is easy to implement. In some cases computational and/or memory savings can be attained.

Although this disclosure has been described in terms of certain embodiments, alterations and permutations of the embodiments will be apparent to those skilled in the art. Although some embodiments have been described with reference to certain technologies, any suitable technology or combination of technologies may be used, such as radio access technology (RAT) including long term evolution (LTE), LTE-Advanced, NR, UMTS, HSPA, GSM, cdma2000, WiMax, WiFi, magnetic storage systems and solid-state drive systems, neural networks, etc. Accordingly, the above description of the embodiments does not constrain this disclosure. Other changes, substitutions, and alterations are possible without departing from the spirit and scope of this disclosure.

Abbreviations:

3GPP 3rd Generation Partnership Project

BLER Block Error Rate

eMBB enhanced Mobility BroadBand

eNB Evolved Node B

eNodeB Evolved Node B

LDPC Low-Density Parity-Check

LTE Long-Term Evolution

NR New Radio

PCM Parity Check Matrix

RAT Radio Access Technology

RRC Radio Resource Control

UE User Equipment

UMTS Universal Mobile Telecommunications System

### EXAMPLE EMBODIMENTS

### Embodiment I

A method comprising deriving the elements of a base matrix H_base_Z with lower Z from a base matrix with a maximum Z (Zₘₐₓ), H_base_Zmax, the deriving comprising right shifting a binary vector representation of all non-negative elements of the base matrix, where Z and Zmax are lift factors.

### Embodiment II

The method of embodiment I, wherein the right shifting is done t times, where t=ceil(log 2(Zmax/Z)).

### Embodiment III

A method comprising: deriving the elements of a base matrix H_base_Z with lower Z from a base matrix with a maximum Z (Zₘₐₓ), H_base_Zmax, the deriving comprising right shifting a binary vector representation of all non-negative elements of the base matrix one or more times.

### Embodiment IV

The method of embodiment I-III, wherein the right shifting is applied only when H_base_Zmax(i,j)>=Z.

### Embodiment V

The method of embodiment IV, further comprising doing the following assignment operation H_base_Z(i,j)=H_base_Zmax(i,j), when H_base_Zmax(i,j)<Z.

### Embodiment VI

The method of embodiment I-V, further comprising using the derived elements of a base matrix H_base_Z to generate the parity code matrix H of an LDPC code.

### Embodiment VII

The method of any of embodiments VI, further comprising:

a. encoding a transport block using the LDPC code.

### Embodiment VIII

The method of any of embodiments VI, further comprising decoding a received transport block using the LDPC code.

### Embodiment IX

A communication node comprising a processor and a memory, the processor operable to: derive the elements of a base matrix H_base_Z with lower Z from a base matrix with a maximum Z (Zₘₐₓ), H_base_Zmax, the deriving comprising right shifting a binary vector representation of all non-negative elements of the base matrix.

### Embodiment X

The communication node of embodiment IX, the processor further operable to use the derived elements of a base matrix H_base_Z to generate a parity code matrix H.

### Embodiment XI

The communication node of embodiment IX, the processor further operable to right shifting the binary vector representation only when H_base_Zmax(i,j)>=Z.

### Embodiment XII

The communication node of embodiments VII-IX, further comprising an encoder for encoding a transport block using the generated parity code matrix and a transmitter for transmitting the transport block.

### Embodiment XIII

The communication node of embodiments IX-XII further comprising a receiver for receiving a transport block and a decoder for decoding the transport block using the generated parity code matrix.

### Embodiment XIV

Embodiments I-XIII for use in any one of a wireless communications network, magnetic storage systems and solid-state drive systems.

1. A method comprising:
deriving the elements of a base matrix H_base_Z with lower Z from a base matrix with a maximum Z (Zₘₐₓ), H_base_Zmax, the deriving comprising right shifting a binary vector representation of all non-negative elements of the base matrix, where Z and Zmax are lift factors.

2. The method of claim 1, wherein the right shifting is done t times, where t=ceil(log 2(Zmax/Z)).

3. A method comprising:
deriving the elements of a base matrix H_base_Z with lower Z from a base matrix with a maximum Z (Zₘₐₓ), H_base_Zmax, the deriving comprising right shifting a binary vector representation of all non-negative elements of the base matrix one or more times.

4. The method of claim 1, wherein the right shifting is applied only when H_base_Zmax(i,j)>=Z.

5. The method of claim 4, further comprising doing the following assignment operation H_base_Z(i,j)=H_base_Zmax(i,j), when H_base_Zmax(i,j)<Z.

6. The method of claim 1, further comprising using the derived elements of a base matrix H_base_Z to generate the parity code matrix H of an LDPC code.

7. The method of claim 1, further comprising encoding a transport block using the LDPC code.

8. The method of claim 1, further comprising decoding a received transport block using the LDPC code.

9. A communication node comprising:
a processor; and
a memory,
the processor operable to derive the elements of a base matrix H_base_Z with lower Z from a base matrix with a maximum Z (Zₘₐₓ), H_base_Zmax, the deriving comprising right shifting a binary vector representation of all non-negative elements of the base matrix.

10. The communication node of claim 9, the processor further operable to use the derived elements of a base matrix H_base_Z to generate a parity code matrix H.

11. The communication node of claim 9, the processor further operable to right shifting the binary vector representation only when H_base_Zmax(i,j)>=Z.

12. The communication node of claim 9, further comprising
an encoder for encoding a transport block using the generated parity code matrix; and a transmitter for transmitting the transport block.

13. The communication node of claim 9 further comprising:
a receiver for receiving a transport block; and
a decoder for decoding the transport block using the generated parity code matrix.

14. (canceled)
